(19) United States
(12) Patent Application Publication
(10) Pub. No.: US 2026/0047117 A1
(43) Pub. Date: Feb. 12, 2026

(54) SEMICONDUCTOR DEVICE

(71) Applicant: Renesas Electronics Corporation, Tokyo (JP)

(72) Inventors: Hitoshi MATSUURA, Tokyo (JP); Shunichi NAKAMURA, Tokyo (JP)

(21) Appl. No.: 19/254,871

(22) Filed: Jun. 30, 2025

(30) Foreign Application Priority Data
Aug. 9, 2024 (JP) 2024-133869

(51) Int. Cl. H10D 12/00; H10D 64/23

(52) U.S. Cl. CPC H10D 12/481; H10D 64/232

(57) ABSTRACT

A semiconductor device has an IGBT (Insulated Gate Bipolar Transistor) and includes a trench gate arranged in a semiconductor substrate, a trench emitter arranged parallel to the gate trench in plan view of the semiconductor substrate, and a contact electrode arranged parallel to the trench emitter in plan view of the semiconductor substrate. The contact electrode protrudes towards the trench emitter in plan view of the semiconductor substrate and has a protruding part connected to the trench emitter.

### CROSS-REFERENCE TO RELATED APPLICATIONS

The disclosure of Japanese Patent Application No. 2024-133869 filed on Aug. 9, 2024, including the specification, drawings and abstract is incorporated herein by reference in its entirety.

### BACKGROUND

This disclosure relates to a semiconductor device.

There is a disclosed technique listed below.

### [Patent Document 1] Japanese Unexamined Patent Application Publication No. 2019-29434

Patent Document 1 discloses a trench gate IGBT (Insulated Gate Bipolar Transistor) that includes a trench gate electrode or a trench emitter electrode between an active region and an inactive region, with the trench gate electrode and trench emitter electrode provided across the inactive region.

### SUMMARY

However, when the contact electrode shares contact with the trench emitter, there was a possibility that the contact width could become too wide to embed the metal plug. Therefore, the purpose of this disclosure is to provide a semiconductor device that achieves good contact between the trench emitter and the contact electrode by devising the layout of the trench emitter and the contact electrode.

Other issues and novel features will become apparent from the description of this specification and the accompanying drawings.

According to one embodiment, the contact electrode protrudes toward the emitter trench in a plan view of the semiconductor substrate and has a protruding portion that connects to the emitter trench.

According to the above-mentioned embodiment, a semiconductor device that achieves good contact between the trench emitter and the contact electrode can be provided by devising the layout of the trench emitter and the contact electrode.

### BRIEF DESCRIPTION OF THE DRAWINGS

FIG. 1 is a schematic cross-sectional view of a related semiconductor device.

FIG. 2A is a diagram showing an example of the layout of the trench emitter, trench gate, and contact electrode according to the embodiment and another embodiment.

FIG. 2B is a diagram showing an example of the layout of the trench emitter, trench gate, and contact electrode according to the embodiment and another embodiment.

FIG. 2C is a diagram showing an example of the layout of the trench emitter, trench gate, and contact electrode according to the embodiment and another embodiment.

FIG. 2D is a diagram showing an example of the layout of the trench emitter, trench gate, and contact electrode according to the embodiment and another embodiment.

FIG. 2E is a diagram showing an example of the layout of the trench emitter, trench gate, and contact electrode according to the embodiment and another embodiment.

FIG. 2F is a diagram showing an example of the layout of the trench emitter, trench gate, and contact electrode according to the embodiment and another embodiment.

FIG. 2G is a diagram showing an example of the layout of the trench emitter, trench gate, and contact electrode according to the embodiment and another embodiment.

FIG. 3 is a diagram showing an example of the dimensions of the layout of the trench emitter, trench gate, and contact electrode according to the embodiment.

FIG. 4 is a diagram showing the relationship between the spacing of the protruding portions of the contact electrode and the electrical characteristics of the semiconductor device.

FIG. 5 is a diagram showing defects when the width of the contact electrode is too wide.

FIG. 6A is a diagram showing an example of applying the layout of this disclosure to a semiconductor device where the trench emitter-trench gate-trench emitter is arranged.

FIG. 6B is a diagram showing an example of applying the layout of this disclosure to a semiconductor device where the trench emitter-trench gate-trench emitter is arranged.

### DETAILED DESCRIPTION

### Embodiments

The embodiments of the present invention will be described below with reference to the drawings. However, the invention according to the claims is not limited to the following embodiments. Also, not all configurations described in the embodiments are necessarily essential as a means for solving the problems. For clarity of explanation, the following description and drawings are appropriately omitted and simplified. In the drawings, the same elements are denoted by the same reference numerals, and repetitive descriptions are omitted as necessary.

### (Description of Related Semiconductor Device)

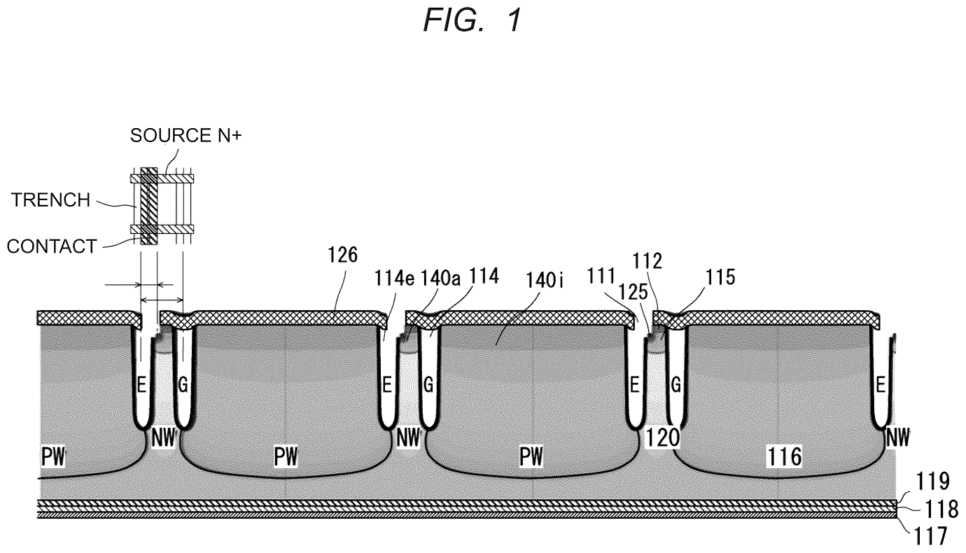

FIG. 1 is a schematic cross-sectional view of a related semiconductor device. The related semiconductor device will be described with reference to FIG. 1. As shown in FIG. 1, the related semiconductor device is an IE-type trench gate IGBT, having a trench gate electrode or a trench emitter electrode between the active cell region and the inactive cell region, and is a GE (gate potential connection trench-emitter potential connection trench) type IGBT (Insulated Gate Bipolar Transistor). Note that the active cell region is narrower than the GG-type IGBT and is referred to as a GE-S (gate potential connection trench-emitter potential connection trench-shrink type) type IGBT.

As shown in FIG. 1, the unit cell region of the GE-S type IGBT includes an active cell region 140a and an inactive cell region 140i, with a trench gate electrode 114 and a trench emitter electrode 114e arranged between the active cell region 140a and the inactive cell region 140i.

As shown in FIG. 1, a P+ type collector region 118 is provided in the semiconductor region on the back surface of the semiconductor substrate, and a metal collector electrode 117 is provided on its surface. An N type field stop region 119 is provided between the N-type drift region 120, which constitutes the main part of the semiconductor substrate, and the P+ type collector region 118. On the N-type drift region in the active cell region 140a, an N type hole barrier region, a P type body region 115, and an N+ type emitter region 112 are provided in order from the bottom. The N+ type emitter region 112 is provided only on the trench gate electrode 114 side. Additionally, an interlayer insulating film 126 is formed on the trench gate electrode 114, trench emitter electrode 114e, P type body region 115, and N+ type emitter region 112, and in the interlayer insulating film 126 portion in the active cell region 140a, a contact groove 111 extending to the inside of the semiconductor substrate is formed. In the bottom semiconductor region of the contact groove 111, a P+ type body contact region 125 and a P+ type latch-up prevention region are provided from the top. Through this contact groove 111, the P type body region 115 and the N+ type emitter region 112 are connected to a metal emitter electrode provided on the interlayer insulating film 126.

Here, the N type hole barrier region is a barrier region to prevent holes from flowing into the passage from the N-type drift region 120 to the N+ type emitter region 112, and its impurity concentration is lower than that of the N+ type emitter region 112 and higher than that of the N-type drift region 120. The presence of this N type hole barrier region effectively prevents holes accumulated in the inactive cell region 140i from entering the emitter passage (the passage from the N-type drift region 120 to the P+ type body contact region 125) of the active cell region 140a.

In contrast, in the N-type drift region 120 in the inactive cell region 140i, a P type floating region 116 and a P type body region 115 are provided in order from the bottom, and the depth of the P type floating region 116 is deeper than the depth of the trench and is distributed to cover the lower end of the trench.

In such a related semiconductor device, there was a problem that it was difficult to embed the metal plug if the width of the contact electrode was wide. Additionally, the contact electrode needs to extend in the depth direction to penetrate the source N+ region. Therefore, if the width of the contact electrode is narrowed, there was a problem that high-precision photolithography would be required.

### (Description of the Layout of the Trench Emitter, Trench Gate, and Contact Electrode According to the Embodiment and Another Embodiment)

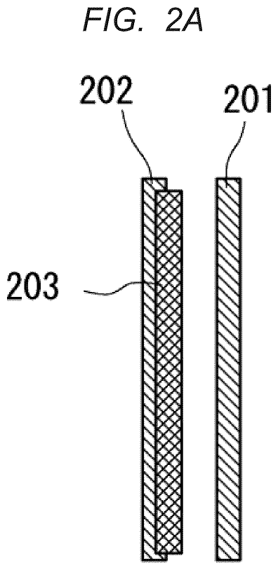

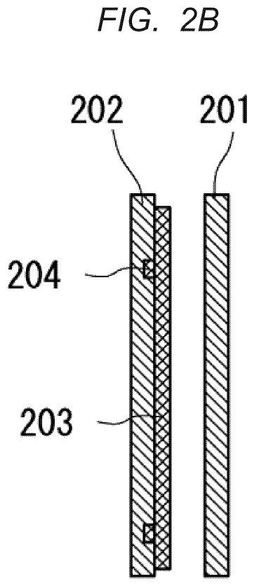

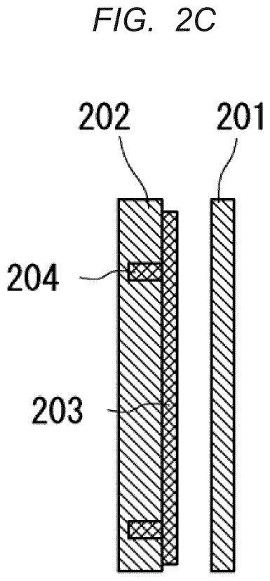

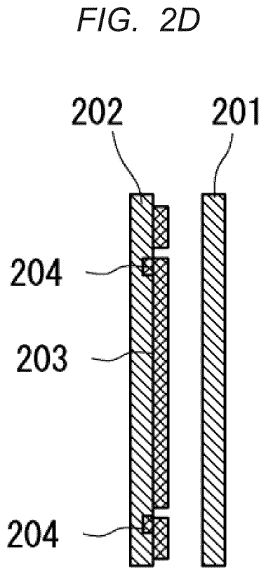

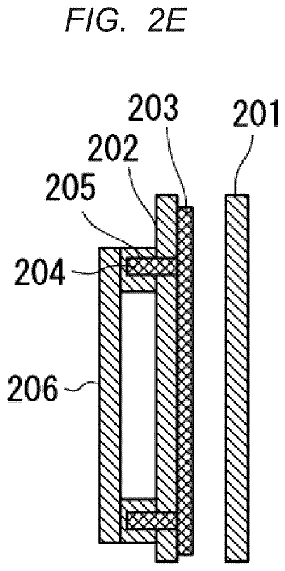

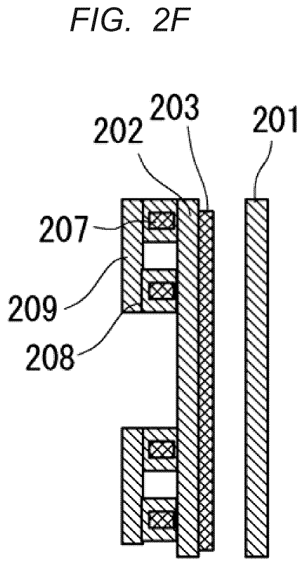

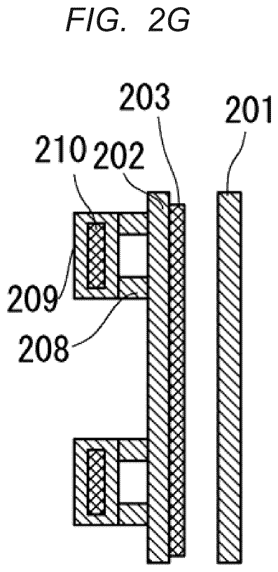

FIG. 2A to FIG. 2G are diagrams showing variations in the layout of the trench emitter, trench gate, and contact electrode according to the embodiment and another embodiment. The layout of the trench emitter, trench gate, and contact electrode according to the embodiment and another embodiment will be described with reference to FIG. 2A to FIG. 2G.

FIG. 2A to FIG. 2G are plan views of the semiconductor substrate viewed from above. FIG. 2A to FIG. 2G are views of the semiconductor substrate in the XY plane in a three-dimensional XYZ coordinate system, viewed from the Z direction. FIG. 2A is a reference. As shown in FIG. 2A, the trench emitter 202 is arranged parallel to the trench gate 201. Additionally, a contact electrode 203 is arranged between the trench emitter 202 and the trench gate 201, parallel to the trench emitter 202. The trench emitter 202 has a region overlapping with the contact electrode 203 parallel to the contact electrode. Such a layout had the problem that the width of the contact electrode had to be widened to ensure electrical connection with both the trench emitter 202 and the P type body region 115.

FIG. 2B is a layout of the trench gate, trench emitter, and contact electrode according to the embodiment. The semiconductor device includes a trench gate 201 arranged on the semiconductor substrate, a trench emitter 202 arranged parallel to the trench gate 201 in a plan view of the semiconductor substrate, and a contact electrode 203 arranged parallel to the trench emitter 202 in a plan view of the semiconductor substrate. The contact electrode 203 protrudes toward the trench emitter 202 in a plan view of the semiconductor substrate and has a protruding portion 204 that connects to the trench emitter 202.

By doing so, the protruding portion 204 can ensure that the trench emitter 202 and the contact electrode 203 make contact reliably.

FIG. 2C is a layout of the trench gate, trench emitter, and contact electrode according to the embodiment. FIG. 2C differs from FIG. 2B in the width of the trench emitter 202. However, in a plan view of the semiconductor substrate, the length of the protruding portion 204 can be extended to ensure contact as long as it is smaller than the width of the trench emitter 202.

FIG. 2D is a layout of the trench gate, trench emitter, and contact electrode according to the embodiment. There are multiple protruding portions 204, and the contact electrode 203 may be arranged spaced apart for each protruding portion 204. In the upper layer, the spaced contact electrodes 203 are electrically connected.

FIG. 2E illustrates the layout of a trench gate, trench emitter, and contact electrode according to the embodiment. In a plan view of the semiconductor substrate, the trench emitter 202 has a protruding portion 205. The protruding portion 204 of the contact electrode 203 has a region overlapping with the protruding portion 205 of the trench emitter 202. The length of the protruding portion 204 of the contact electrode 203 is smaller than the width of the protruding portion 205 of the trench emitter 202. Additionally, there are multiple protruding portions 205 of the trench emitter 202. Furthermore, the semiconductor device includes a connecting region 206 where the protruding portion 205 of the trench emitter 202 is connected to the protruding portion 205 of another trench emitter 202 at the end.

By doing so, the protruding portion 204 of the contact electrode can be extended, ensuring reliable contact between the trench emitter and the contact electrode.

FIG. 2F illustrates the layout of a trench gate, trench emitter, and contact electrode according to another embodiment. The semiconductor device includes a trench gate 201 arranged on the semiconductor substrate, a trench emitter 202 arranged parallel to the trench gate 201 in a plan view of the semiconductor substrate, and a contact electrode 203 arranged parallel to the trench emitter 202 in a plan view of the semiconductor substrate. The contact electrode 203 is divided into multiple regions in a plan view of the semiconductor substrate and has a region overlapping with the trench emitter 202.

Additionally, in a plan view of the semiconductor substrate, the trench emitter 202 has a protruding portion 208, and the contact electrode 203 may have a region 207 overlapping with the protruding portion 208 of the trench emitter 202. Furthermore, there are multiple protruding portions 208 of the trench emitter 202. The semiconductor device also includes a connecting region 209 where the protruding portion 208 of the trench emitter 202 is connected to the protruding portion 208 of another trench emitter 202 at the end.

In the upper layer, region 207 overlapping with the separated contact electrode 203 is electrically connected. This allows for greater design flexibility in the layout of the contact electrode.

FIG. 2G illustrates the layout of a trench gate, trench emitter, and contact electrode according to another embodiment. In a plan view of the semiconductor substrate, the trench emitter 202 has multiple protruding portions 208. The semiconductor device includes a connecting region 209 where the protruding portion 208 of one trench emitter 202 is connected to the protruding portion 208 of another trench emitter 202 at the end. The contact electrode 203 has a region 210 overlapping with the connecting region 209.

In the upper layer, region 210 overlapping with the separated contact electrode 203 is electrically connected. This allows for greater design flexibility in the layout of the contact electrode.

With the above configuration, by devising the layout of the trench emitter and contact electrode, it is possible to provide a semiconductor device that ensures good contact between the trench emitter and the contact electrode.

### (Description of Dimensional Examples of the Layout of the Trench Emitter, Trench Gate, and Contact Electrode According to the Embodiment)

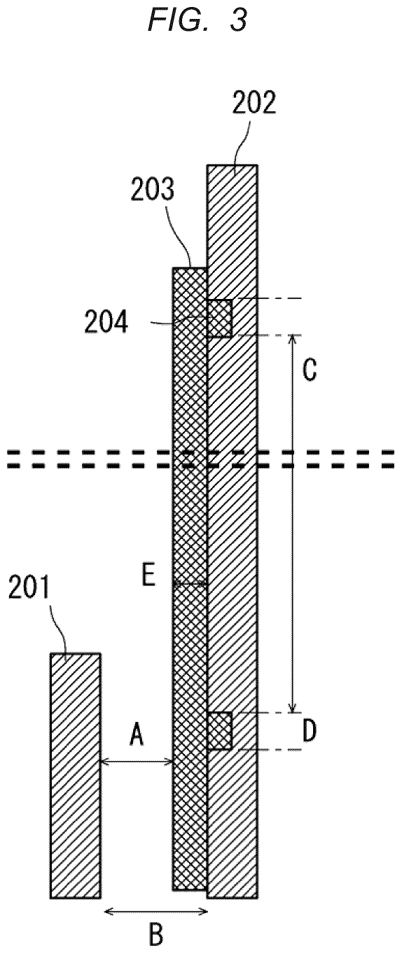

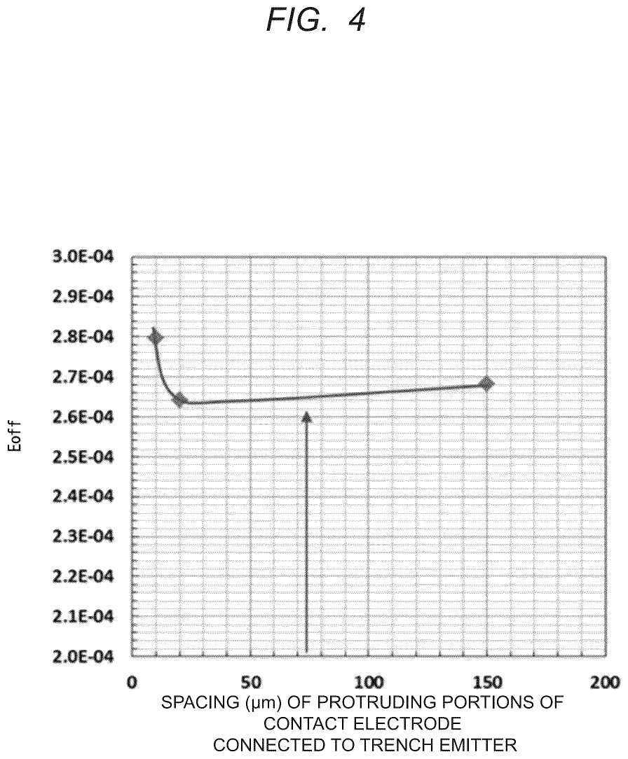

FIG. 3 shows a dimensional example of the layout of the trench emitter, trench gate, and contact electrode according to the embodiment. FIG. 4 shows the relationship between the spacing of the protruding portions of the contact electrode and the electrical characteristics of the semiconductor device. The dimensional example of the layout of the trench emitter, trench gate, and contact electrode according to the embodiment will be described with reference to FIGS. 3 and 4.

As shown in FIG. 3, it is preferable that dimensions A and B are similar to those of the related semiconductor device. Therefore, the width of the trench emitter is preferably between 0.3 micrometers and 0.8 micrometers, similar to the related semiconductor device. The width E of the contact electrode 203 is preferably between 0.2 micrometers and 0.5 micrometers.

The length of the protruding portion 204 is preferably between 0.2 micrometers and 0.5 micrometers, and the width D of the protruding portion 204 is preferably between 0.2 micrometers and 0.5 micrometers.

Here, consider the spacing C between the protruding portions 204. A structure is intentionally created where only the trench emitter 202 and the protruding portion 204 of the contact electrode are connected, and the trench emitter 202 and the contact electrode 203 are not in contact at all. In this state, as shown in FIG. 4, when the spacing C of the protruding portion 204 varies from 0 to 150 micrometers, it was found that the electrical characteristics deteriorate when it is less than 10 micrometers. On the other hand, if the spacing C of the protruding portion 204 is too large, the number of contact electrodes 203 connected to the trench emitter 202 decreases, causing electrical delay and theoretically deteriorating the characteristics. Therefore, it is preferable to set the spacing C of the protruding portion 204 between 20 micrometers and 150 micrometers. Particularly, it is preferable that the spacing C of the protruding portion 204 is 75 micrometers, which is the center of 20 micrometers to 150 micrometers, where the characteristics do not change and spacing can be provided.

### (Description of the Size of the Contact Electrode According to the Embodiment)

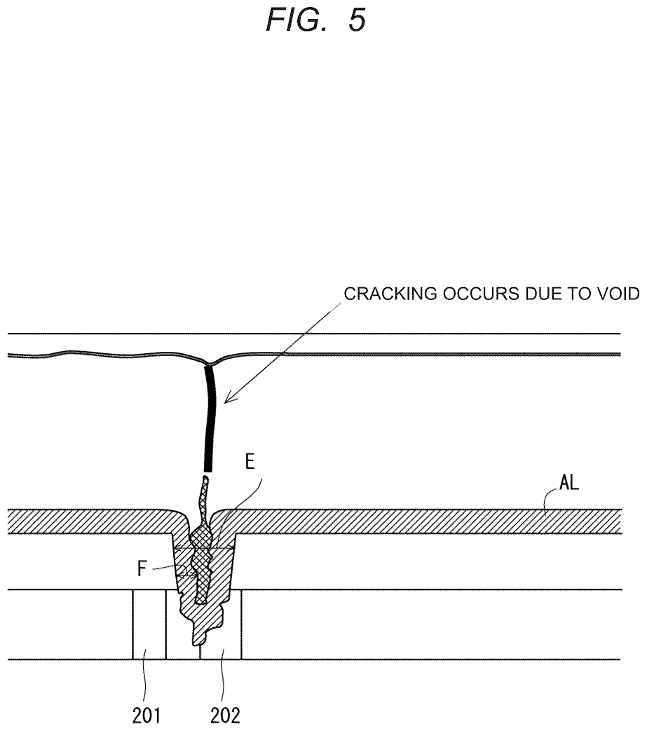

FIG. 5 shows a defect when the width of the contact electrode is too wide. The size of the contact electrode will be described with reference to FIG. 5.

As shown in FIG. 5, if the size E of the contact electrode is greater than twice the thickness of the metal plug F, voids occur, and cracking occurs at the upper part.

Therefore, it is preferable that the width of the contact electrode in a plan view of the semiconductor substrate is smaller than twice the thickness of the metal layer forming the contact electrode.

(Description of an Example where the Layout of the Present Disclosure is Applied to a Semiconductor Device with Trench Emitter-Trench Gate-Trench Emitter Arrangement)

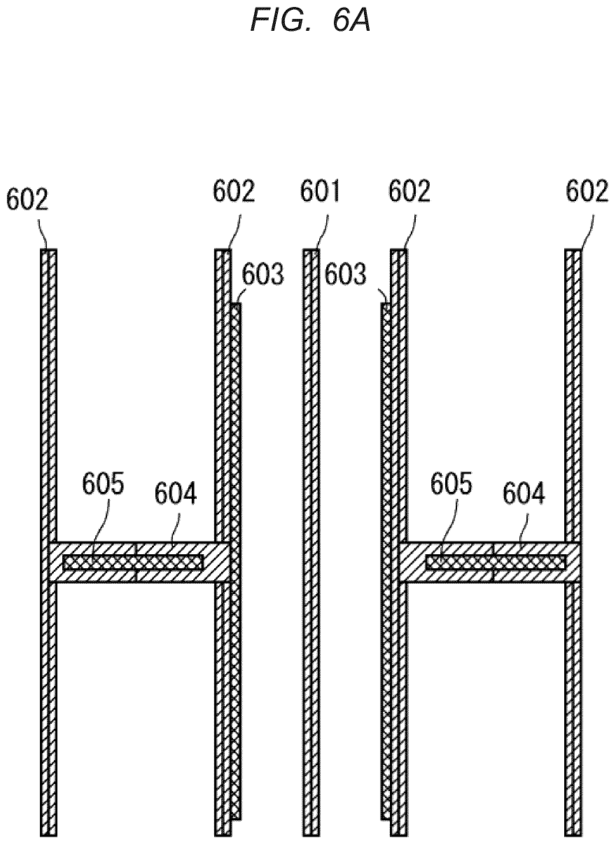

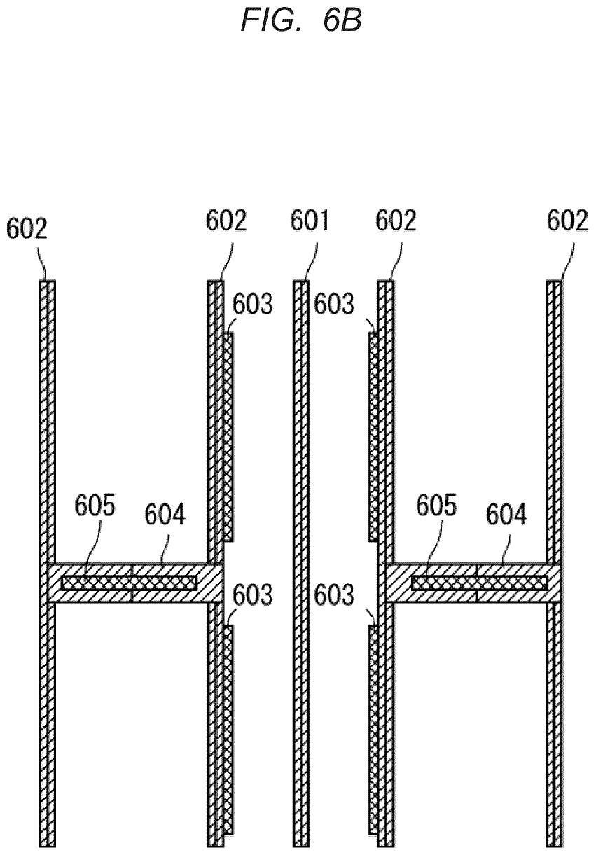

FIG. 6A and FIG. 6B show examples where the layout of the present disclosure is applied to a semiconductor device with a trench emitter-trench gate-trench emitter arrangement. An example where the layout of the present disclosure is applied to a semiconductor device with a trench emitter-trench gate-trench emitter arrangement will be described with reference to FIG. 6A and FIG. 6B.

FIG. 6A and FIG. 6B show examples where the layout of the present disclosure is applied to an EGE-type IGBT. As shown in FIG. 6A, the semiconductor device includes a trench gate 601 arranged on the semiconductor substrate, trench emitters 602 arranged parallel to the trench gate 601 on both sides in a plan view of the semiconductor substrate, and a contact electrode 603 arranged between the trench gate 601 and the trench emitters 602 in a plan view of the semiconductor substrate. The contact electrode 603 is divided into multiple regions in a plan view of the semiconductor substrate and has a region overlapping with the trench emitters 602.

Additionally, in a plan view of the semiconductor substrate, the trench emitters 602 have a protruding portion 604. The multiple regions of the contact electrode 603 may have a region 605 overlapping with the protruding portion 604 of the trench emitters 602. In the upper layer, region 605 overlapping with the contact electrode 603 is electrically connected. This ensures reliable contact between the trench emitter and the contact electrode in the EGE (trench emitter-trench gate-trench emitter) type IGBT.

As shown in FIG. 6B, the contact electrode 603 arranged parallel to trench emitters 602 may be divided into island-like sections. In the upper layer, region 605 overlapping with the contact electrode 603 is electrically connected. This improves the design flexibility of the layout in the EGE-type IGBT structure.

With the above configuration, by devising the layout of the trench emitter and contact electrode, it is possible to provide a semiconductor device that ensures good contact between the trench emitter and the contact electrode.

For example, in the semiconductor device according to the above embodiment, the conductivity type (p-type or n-type) of the semiconductor substrate, semiconductor layer, diffusion layer (diffusion region), etc., may be inverted. Therefore, when one of the conductivity types of n-type and p-type is the first conductivity type and the other conductivity type is the second conductivity type, the first conductivity type can be p-type and the second conductivity type can be n-type, or conversely, the first conductivity type can be n-type, and the second conductivity type can be p-type.

Although the invention made by the inventors has been specifically described based on the embodiment, the present invention is not limited to the embodiment already described, and it is needless to say that various modifications can be made without departing from the gist thereof.

What is claimed is:

1. A semiconductor device having an IGBT (Insulated Gate Bipolar Transistor), the semiconductor device comprising:
a trench gate arranged in a semiconductor substrate;
a trench emitter arranged parallel to the trench gate in plan view of the semiconductor substrate; and
a contact electrode arranged parallel to the trench emitter in plan view of the semiconductor substrate,
wherein the contact electrode has a protruding part protruding toward the trench emitter in plan view of the semiconductor substrate and connected to the trench emitter.

2. The semiconductor device according to claim 1,
wherein a length of the protruding part in plan view of the semiconductor substrate is smaller than a width of the trench emitter.

3. The semiconductor device according to claim 2,
wherein in plan view of the semiconductor substrate, the width of the trench emitter is from 0.3 micrometers to 0.8 micrometers, the length of the protruding part is from 0.2 micrometers to 0.5 micrometers, and a width of the protruding part is from 0.2 micrometers to 0.5 micrometers.

4. The semiconductor device according to claim 1,
wherein the protruding part includes a plurality of protruding parts, and
wherein in plan view of the semiconductor substrate, the contact electrode is arranged separately for each of the plurality of protruding parts.

5. The semiconductor device according to claim 1, wherein in plan view of the semiconductor substrate,
the trench emitter has a protruding part,
the protruding part of the contact electrode has a region overlapping with the protruding part of the trench emitter, and
the length of the protruding part of the contact electrode is smaller than a width of the protruding part of the trench emitter.

6. The semiconductor device according to claim 5,
wherein the protruding part of the trench emitter includes a plurality of protruding parts, and
wherein the semiconductor device includes a connecting region where an end of the protruding part of the trench emitter is connected to an end of the protruding part of another trench emitter.

7. The semiconductor device according to claim 1,
wherein the protruding part includes a plurality of protruding parts, and
wherein in plan view of the semiconductor substrate, the plurality of protruding parts are arranged at intervals of 20 micrometers to 150 micrometers.

8. The semiconductor device according to claim 1,
wherein in plan view of the semiconductor substrate, a width of the contact electrode is smaller than twice a thickness of a metal layer forming the contact electrode.

9. A semiconductor device having an IGBT (Insulated Gate Bipolar Transistor), the semiconductor device comprising:
a trench gate arranged in a semiconductor substrate;
a trench emitter arranged parallel to the trench gate in plan view of the semiconductor substrate; and
a contact electrode arranged parallel to the trench emitter in plan view of the semiconductor substrate, wherein the contact electrode is divided into a plurality of regions in plan view of the semiconductor substrate and has a region overlapping with the trench emitter.

10. The semiconductor device according to claim 9,
wherein in plan view of the semiconductor substrate, the trench emitter has a protruding part, and the contact electrode has a region overlapping with the protruding part of the trench emitter.

11. The semiconductor device according to claim 10,
wherein the trench emitter includes a plurality of protruding parts, and
wherein the semiconductor device includes a connecting region where an end of the protruding part of the trench emitter is connected to an end of the protruding part of another trench emitter.

12. The semiconductor device according to claim 9, wherein in plan view of the semiconductor substrate, the trench emitter includes a plurality of protruding parts;
the semiconductor device includes a connecting region where an end of the protruding part of one trench emitter is connected to an end of the protruding part of another trench emitter; and
the contact electrode has a region overlapping with the connecting region.

13. The semiconductor device according to claim 9,
wherein in plan view of the semiconductor substrate, a width of the trench emitter is 0.3 micrometers to 0.8 micrometers, and
a width of the contact electrode is 0.2 micrometers to 0.5 micrometers.

14. The semiconductor device according to claim 9,
wherein in plan view of the semiconductor substrate, a width of the contact electrode is smaller than twice a thickness of a metal layer forming the contact electrode.
